(19) United States
(12) Patent Application Publication
(10) Pub. No.: US 2013/0328732 A1
(43) Pub. Date: Dec. 12, 2013

(54) TOUCHSCREEN AND MANUFACTURING PROCESS THEREOF

(71) Applicant: FUJITSU COMPONENT LIMITED, Tokyo (JP)

(72) Inventor: Kousuke SHIMIZU, Tokyo (JP)

(73) Assignee: FUJITSU COMPONENT LIMITED, Tokyo (JP)

(21) Appl. No.: 13/845,261

(22) Filed: Mar. 18, 2013

(30) Foreign Application Priority Data
Jun. 7, 2012 (JP) 2012-129878

(51) Int. Cl. H01Q 1/22; H05K 3/30

(52) U.S. Cl. CPC H01Q 1/22; H05K 3/30
USPC 343/720; 29/832

(57) ABSTRACT

A touchscreen includes a substrate including a conductive layer on a part of its surface, and an antenna being situated in a region where the conductive layer is not provided.

### CROSS-REFERENCE TO RELATED APPLICATIONS

This application is based upon and claims the benefit of priority of the prior Japanese Patent Application No. 2012-129878, filed Jun. 7, 2012, the entire contents of which are incorporated herein by reference.

### BACKGROUND OF THE INVENTION

1. Field of the Invention

The present invention relates to a touchscreen and a manufacturing process thereof.

2. Description of the Related Art A touchscreen including a substrate having a transparent conductive layer has been known (see JP-A-2010-40424 and JP-B-4587958). In recent years such a touchscreen has been widely used for a device with communication capability such as a mobile phone and an e-book reader.

There is a need for a touchscreen including an antenna having improved sensitivity for data communication usage, and for a manufacturing process for manufacturing such a touchscreen.

### SUMMARY OF THE INVENTION

According to one embodiment of the present invention, a touchscreen comprises: a substrate including a conductive layer on a part of its surface; and an antenna being situated in a region where the conductive layer is not provided.

According to another embodiment of the present invention, a manufacturing process for manufacturing a touchscreen comprising an antenna therein comprises: forming a wiring pattern and an electrode on a conductive layer formed on a substrate; removing a part of the conductive layer; and positioning the antenna in a region where the conductive layer is removed.

### BRIEF DESCRIPTION OF THE DRAWINGS

FIG. 1 is a schematic plan view illustrating a touchscreen according to one embodiment;

FIG. 2 is a schematic sectional view taken along line II-II of FIG. 1;

FIG. 3A through FIG. 3D show steps of forming a substrate including a transparent conductive layer;

FIG. 4 shows a step of manufacturing a touchscreen;

FIG. 5 is a schematic sectional view illustrating a touchscreen according to a comparative example.

### DESCRIPTION OF EMBODIMENTS

Embodiments of the present invention will be described below with reference to the accompanying drawings. Illustrated constituent elements may be modified in size in relation to one another from the practical application for better understanding.

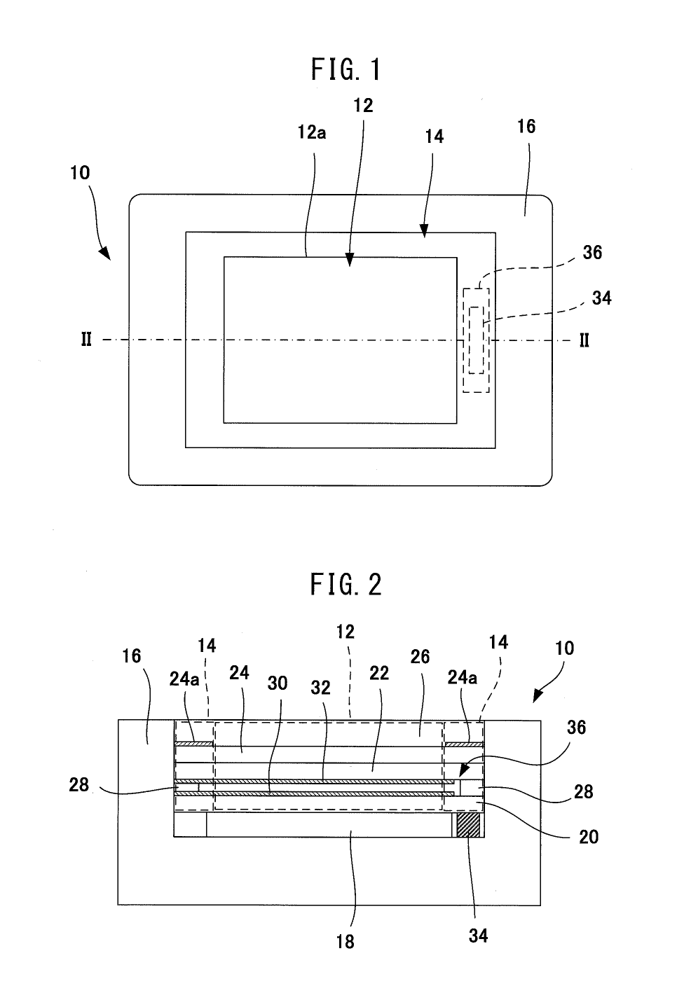

FIG. 1 is a schematic plan view illustrating a touchscreen 10 according to one embodiment. FIG. 2 is a schematic sectional view taken along line II-II of FIG. 1. The touchscreen 10 includes a detection part 12 having an operation surface 12a for detecting a contacting operation on the operation surface 12a, a frame part 14 surrounding the peripheral of the detection part 12, and a housing 16 surrounding the peripheral of the frame part 14. The touchscreen 10 performs a function associated with a contacting operation by a user's finger or stylus at a certain position on the operation surface 12a.

As shown in FIG. 2, the touchscreen 10 has a stacked structure formed from a plurality of plate members which are stacked on top of one another and situated in a recess formed on the housing 16. The touchscreen 10 includes a pair of a first substrate 20 and a second substrate 22 extending so as to face each other and extending over the detection part 12 and the frame part 14, a design layer 24 having a printed design part 24a which is formed by printing a desirable design thereon, and a protection layer 26 for defining a surface of the touchscreen 10. An LCD part 18 is provided below the first substrate 20 of the touchscreen 10.

The LCD part 18 can be formed from a well-known LCD panel and backlight device, and thus a detailed explanation thereon will be omitted. The first substrate 20 and the second substrate 22 may be formed from a transparent film or glass such as polyethylene terephthalate (PET), polyethylene naphthalate (PEN), polycarbonate (PC) and polypropylene (PP). The first substrate 20 and the second substrate 22 may be formed from either the same material or different materials. For example, the first substrate 20 is formed from glass, while the second substrate 22 is formed form a film such as a PP film. The first substrate 20 and the second substrate 22 may also be formed from a PET film. In particular, when the first substrate 20 and the second substrate 22 are formed from a flexible film, respectively, an additional plastic support member may also be provided.

The first substrate 20 and the second substrate 22 are provided so as to face each other and be spaced apart from each other by a spacer 28 which is, for example, an adhesive tape, on both surfaces of which adhesive is applied. The first substrate 20 and the second substrate 22 are provided with certain wiring patterns and electrodes formed from, for example, printed silver ink. These wiring patterns and electrodes on the first substrate 20 and the second substrate 22 constitute a detection circuit for detecting a contacting operation and a corresponding contacting position on the operation surface 12a. The present invention can be applied to either a resistive touchscreen or a capacitive touchscreen, both of which are widely used in the art. The configuration and function of either type of touchscreen is well known, and thus a detailed explanation thereon will be omitted.

The first substrate 20 and the second substrate 22 have transparent conducive layers 30 and 32, respectively, on surfaces facing each other. The transparent conductive layers 30 and 32 may be formed from, for example, indium tin oxide (ITO). ITO is provided on the surfaces of the first substrate 20 and the second substrate 22 by means of sputtering. The transparent conductive layers 30 and 32 are thin membranes having a thickness in the range from several nanometers to tens of nanometers, for example. The transparent conductive layers 30 and 32 extend at least over a region where the detection part 12 is provided. On the other hand, the transparent conductive layers 30 and 32 are not provided on a region 36, which may also be referred to as a “removed region.”

The design layer 24 includes a printed design part 24a having a certain design intended to prevent the electrode and the like on the first substrate 20 and the second substrate 22 from being seen. For example, the printed design part 24a may be printed on the design layer 24. The printed design part 24a defines a region taken up by the frame part 14. The frame part 14 is formed to surround the peripheral of the detection part 12 which also serves as a display surface for displaying images (see FIG. 1).

The protection layer 26 is situated on the outermost of the stacked structure and forms a surface of the touchscreen 10. The protection layer 26 protects other layers of the stacked structure from small particles such as dust, from dirt or from scratches.

The touchscreen 10 includes an antenna 34 for receiving an electromagnetic wave so as to perform various data communication. The antenna 34 is provided below the frame part 14 of the touchscreen 10.

As can be seen in FIG. 2, the antenna 34 is situated in a region 36 where the transparent conductive layers 30 and 32 are not formed. The transparent conductive layers 30 and 32 in the region 36 have been removed by dry etching such as laser etching. If laser etching is used, manufacturing cost can be reduced, since a large facility is not required and an etching process can be relatively simple. However, the present invention should not be limited to a particular embodiment where laser etching is used. For example, other types of dry etching may be used, or alternatively, wet etching may also be used to remove the transparent conductive layers 30 and 32.

According to the embodiment in which the transparent conductive layers 30 and 32 are not present over the antenna 34, reception of the antenna 34 can be improved. In the case where the transparent conductive layers 30 and 32 are present on a passage of an electromagnetic wave received by the antenna 34, an electromagnetic wave coming toward the antenna 34 can interfere with the transparent conductive layers 30 and 32. As a result, the electromagnetic wave can be blocked, and reception of the antenna 34 can be impaired.

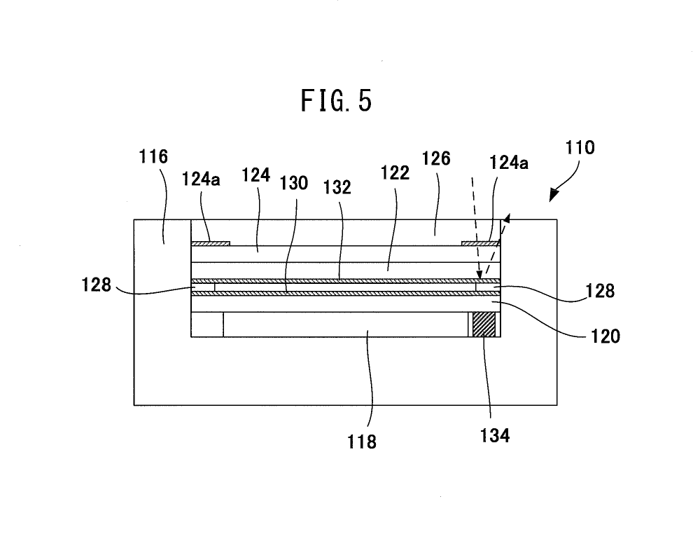

FIG. 5 is a schematic sectional view illustrating a touchscreen 110 according to a comparative example. FIG. 5 is a sectional view corresponding to FIG. 2. In the touchscreen 110 in this comparative example, the transparent conductive layers 130 and 132 are provided on entire surfaces of the first and second substrates 120 and 122. In other words, the transparent conductive layers 130 and 132 are also present over the antenna 134. Therefore, as illustrated by dashed arrows in FIG. 5, an electromagnetic wave can be blocked by the transparent conductive layers 130 and 132, failing to reach the antenna 134. Consequently, reception of the antenna 134 can be impaired.

In contrast, in the touchscreen 10 according to the embodiment, the transparent conductive layers 30 and 32 are not provided over the antenna 34. Since nothing which blocks an electromagnetic wave is provided over the antenna 34, reception of the antenna 34 can be improved.

As described above, if dry etching is used to remove the transparent conductive layers 30 and 32, manufacturing cost can be reduced. On the other hand, a transparent conductive layer may be removed together with a substrate. However, flatness of the touchscreen can be maintained if dry etching is used, compared to the case where a transparent conductive layer is removed together with a substrate. In the latter case, an additional member is required to fill the removed part. However, there is no need to use any additional member if no part of substrate is removed.

The transparent conductive layers 30 and 32 may also be removed not only in a part of a region delimited by the contour of the antenna 34, but also in the peripheral thereof. In other words, the transparent conductive layers 30 and 32 may be removed over an area larger than the region delimited by the contour of the antenna 34. Alternatively, the transparent conductive layers 30 and 32 may also be removed over an area smaller than the region delimited by the contour of the antenna 34. To what extent the transparent conductive layers 30 and 32 should be removed depends on design requirements such as space available in the touchscreen 10, a positional relationship with other parts and reception requirements.

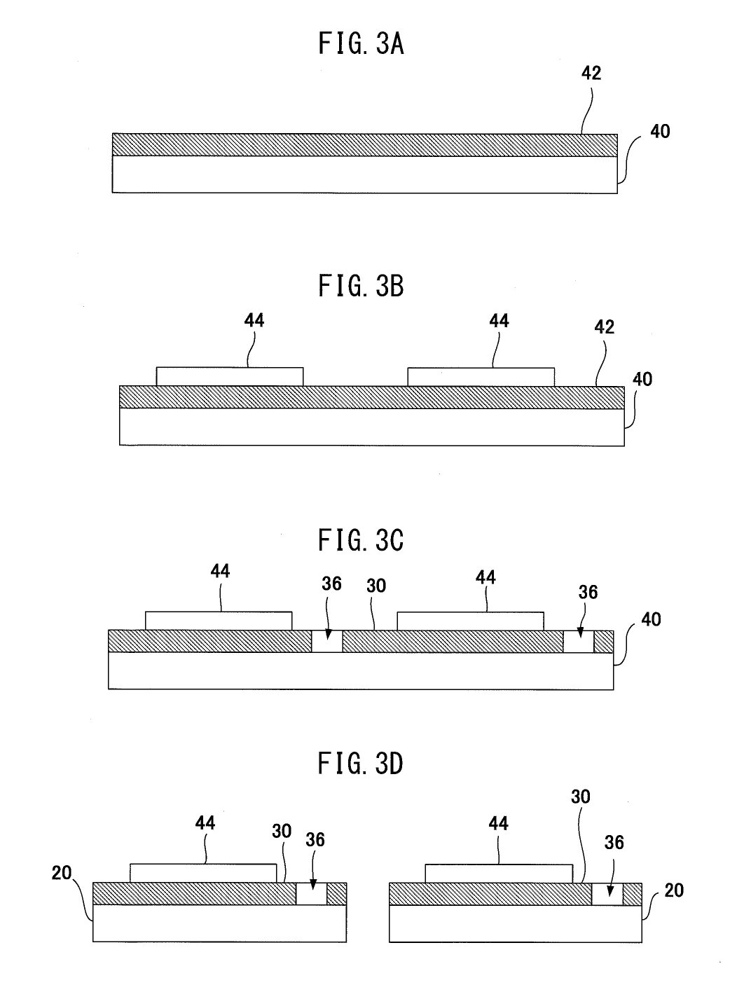

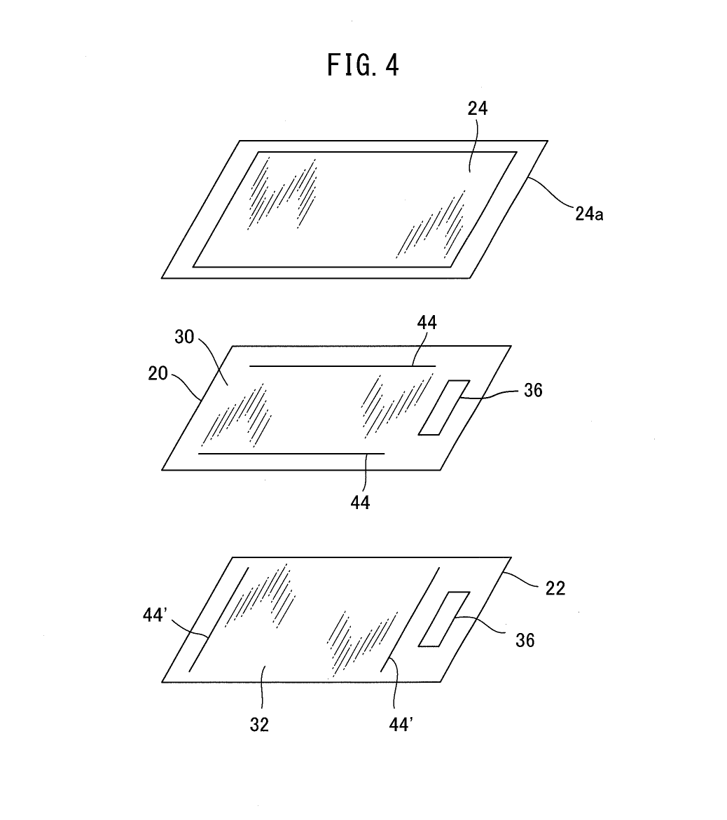

A process for manufacturing the touchscreen 10 according to the embodiment will now be described with reference to FIGS. 3A to 3D and 4. FIGS. 3A to 3D show a step of forming a substrate including a transparent conductive layer, respectively. FIG. 4 shows a step of manufacturing the touchscreen.

First, a transparent plate member 40 from which the first substrate 20 or the second substrate 22 is to be formed is prepared. The plate member 40 is provided with a transparent conductive layer 42 formed from ITO by sputtering, for example. Wiring patterns 44 are then formed on the transparent conductive layer 42 (see FIG. 3B). For example, the wiring patterns 44 are formed by printing silver ink on the transparent conductive layer 42. The wiring patterns 44 are formed so as to be spaced apart from each other, as illustrated. A part of the transparent conductive layer 42 where the antenna 34 is to be provided is then removed by laser etching so as to form a removed region 36 (see FIG. 3C). Then, the plate member 40 is cut and separated to respective substrates used for the touchscreen 10 (for example, the first substrate 20 or the second substrate 22; in this case the first substrate 20 is illustrated) (see FIG. 3D). In this way, the first substrate 20 is provided. The second substrate 22 is also provided in a similar process with the shape of wiring pattern 44 modified as necessary.

The first substrate 20 and the second substrate 22 provided according to the above process are attached to each other with the design layer 24 so as to form the stacked structure (FIG. 4). FIG. 4 shows the design layer 24, the first substrate 20 and the second substrate 22, respectively, in an exploded perspective view. The second substrate 22 has a wiring pattern 44′ formed thereon, which is different from the wiring pattern 44 on the first substrate 20.

In relation to the stacked structure provided in the above way, the antenna 34 is provided below the removed region 36. With such a positional relation between the antenna 34 and the transparent conductive layers 30 and 32, reception of the antenna 34 can be prevented from being impaired.

Although the embodiment where a certain part of the transparent conductive layer is removed from the substrate has been described, the transparent conductive layer may also be formed, in the first place, only on an area excluding a certain part of the substrate with the aid of masking. In the latter case, a process for removing can be omitted.

Although a particular embodiment of the present invention has been described above, it would be obvious for a person skilled in the art to implement the present invention by combining features explicitly or implicitly described in the specification.

1. A touchscreen comprising:
a substrate including a conductive layer on a part of its surface; and
an antenna being situated in a region where the conductive layer is not provided.

2. The touchscreen according to claim 1, wherein the region where the antenna is situated is formed by removing a part of the conductive layer from the substrate.

3. A manufacturing process for manufacturing a touchscreen comprising an antenna therein, the process comprising:
forming a wiring pattern and an electrode on a conductive layer formed on a substrate;
removing a part of the conductive layer; and
positioning the antenna in a region where the conductive layer is removed.

4. The manufacturing process according to claim 3, wherein removing a part of the conductive layer is carried out by dry etching.
